(19) United States
(12) Patent Application Publication
(10) Pub. No.: US 2013/0153939 A1
(43) Pub. Date: Jun. 20, 2013

(54) ORGANIC LIGHT EMITTING DISPLAY DEVICE WITH ENHANCED EMITTING PROPERTY AND PREPARATION METHOD THEREOF

(71) Applicants: Won-Kyu Lee, Seoul (KR); June-Woo Lee, Yongin-si (KR); Young-Jin Chang, Yongin-si (KR); Jae-Hwan Oh, Osan-si (KR); Seong-Hyun Jin, Cheonan-si (KR)

(72) Inventors: Won-Kyu Lee, Seoul (KR); June-Woo Lee, Yongin-si (KR); Young-Jin Chang, Yongin-si (KR); Jae-Hwan Oh, Osan-si (KR); Seong-Hyun Jin, Cheonan-si (KR)

(21) Appl. No.: 13/591,201

(22) Filed: Aug. 21, 2012

(30) Foreign Application Priority Data
Dec. 16, 2011 (KR) 10-2011-0136042

(51) Int. Cl. H01L 27/32; H01L 51/56

(52) U.S. Cl. 257/88; 438/34; 257/E27.118; 257/E51.018

(57) ABSTRACT

An organic light emitting display device in which an upper electrode and power supply lines are connected through through-holes such that charges can be smoothly supplied to the upper electrode of the organic light emitting display device, making it possible to improve light emitting efficiency.

### CROSS-REFERENCE TO RELATED APPLICATION

This application claims priority to and the benefit of Korean Patent Application No. 10-2011-0136042, filed on Dec. 16, 2011, in the Korean Intellectual Property Office, the entire content of which is incorporated herein by reference.

### BACKGROUND

1. Field

The following description relates to an organic light emitting display device having an improved light emitting efficiency.

2. Description of the Related Art

In recent years, organic light emitting display devices are being spotlighted in the field of display technology. Such an organic light emitting display device is a type of display device using light generated when electrons and holes are coupled together to form excitons, and then the excitons change from an excited state to a ground state to thereby emit light.

The organic light emitting display device includes an electrode for injecting holes, an electrode for injecting electrons, and a light emitting layer, and has a structure where the light emitting layer is stacked between the electrode for injecting the holes (i.e., the anode) and the electrode for injecting the electrons (i.e., the cathode). In more detail, after electrons are injected from the cathode of the organic light emitting display device and holes are injected from the anode of the organic light emitting device, the electrons and the holes are moved in opposite directions by an external electric field and are then coupled together in a light emitting layer to form excitons, and then the excitons change from an excited state to a ground state to thereby emit light. The light emitting layer of the organic light emitting display device is formed of an organic monomer or an organic polymer.

FIG. 1 schematically illustrates a structure of an organic light emitting display device.

The organic light emitting display device of FIG. 1 includes a substrate 10, semiconductor layers 20, an insulation layer 30, anodes 40, pixel defining layers 50, light emitting layers 60, and a cathode 70.

In more detail, the semiconductor layers 20 are formed on the transparent or non-transparent substrate 10, and the insulation layer 30 is formed on the semiconductor layer 20. The anodes 40 are formed on the insulation layer 30 such that they are electrically coupled to the semiconductor layers 20. The anodes 40 are defined in units of pixels by the pixel defining layers 50. The light emitting layers 60 are formed on the anodes 40 defined in units of pixels. The light emitting layers 60 may be defined into red light emitting layers 61, green light emitting layers 62, and blue light emitting layers 63. The cathode 70 is formed on the light emitting layers 61, 62, and 63 and the pixel defining layers (PDLs) 50.

FIG. 2 illustrates a structure where multiple organic material layers are stacked on and under a light emitting layer 60 of the organic light emitting display device. A hole injection layer 65 and a hole transport layer 66 are formed between the light emitting layer 60 and an anode 40, and an electron transport layer 68 and an electron injection layer 69 are formed between the light emitting layer 60 and a cathode 70. For reference, the light emitting layer 60, the hole injection layer 65, the hole transport layer 66, the electron transport layer 68, and the electron injection layer 69 are formed of an organic material, so they are all called organic material layers. Also, since the electron injection layer 69 is formed of a metal element or a composite of metal elements in many cases, it may be defined as a separate layer not being included in the organic material layers.

Such an organic light emitting display device includes a plurality of pixels such as red light emitting layers (red pixels), green light emitting layers (green pixels), and blue light emitting layers (blue pixels), and a full color can be expressed by combining the pixels.

FIG. 3 illustrates the organic light emitting display device more specifically. Referring to FIG. 3, the semiconductor layers 20 include gate electrodes 22, drain electrodes 23, and source electrodes 24, which are separated by an interlaying insulation layer (gate insulation layer) 21. Here, the anodes 40 are connected to the drain electrodes 23 of the semiconductor layers 20.

In the related organic light emitting display device, a wire 81 is formed in an upper protective substrate 80 to supply electric power to the cathode 70, i.e. an upper electrode, so that a power supply of the lower substrate 10 is connected to the cathode 70. In more detail, as illustrated in FIG. 3, a metal pad 82 and the wire 81 are disposed in the upper protective substrate 80 such that the cathode 70 and the wire 81 are connected to each other, and a separate conductive wire 90 is formed when the lower substrate 10 and the upper protective substrate 80 are seamed and sealed, so as to connect a lower power source to the wire 81.

However, when a power supply is connected to the cathode 70, i.e. the upper electrode in the above-mentioned structure, charges cannot be smoothly supplied to the cathode 70. In particular, in a large area organic light emitting display device, it is difficult to uniformly supply charges over the entire cathode 70 having a large area. Consequently, there is a limit in obtaining excellent light emitting characteristics.

### SUMMARY

Accordingly, an aspect of an embodiment of the present invention is directed toward an organic light emitting display device by which charges can be smoothly supplied even to an upper electrode.

An aspect of an embodiment of the present invention is directed toward an organic light emitting display device by which charges can be smoothly supplied to an upper electrode located on a light emitting surface side in a top emission type organic light emitting display device, thereby improving light emitting efficiency.

An aspect of an embodiment of the present invention is directed toward a light emitting display device in which an electric power is smoothly supplied to a light emitting surface electrode of a top-emission organic light emitting display device to improve its light emitting efficiency.

According to an embodiment of the present invention, there is provided an organic light emitting display device including: a substrate; semiconductor layers formed on the substrate; power supply lines formed on the substrate to be spaced apart from the semiconductor layers; insulation layers formed on the semiconductor layers and the power supply lines; first electrodes formed on the insulation layers; pixel defining layers defining the first electrodes in units of pixels; light emitting layers formed on the first electrodes defined in units of pixels by the pixel defining layers; through-holes formed on the power supply lines and passing through the insulation layers and the pixel defining layers; and a second electrode formed on the light emitting layers and the pixel defining layers and electrically coupled to the power supply lines through the through-holes.

According to an exemplary embodiment of the present invention, hole injection layers and/or hole transport layers are disposed between the first electrodes and the light emitting layers.

According to an exemplary embodiment of the present invention, electron transport layers and/or electron injection layers are disposed between the light emitting layers and the second electrode.

According to an exemplary embodiment of the present invention, the first electrodes are anodes, and the second electrode is a cathode.

According to an exemplary embodiment of the present invention, the first electrodes are electrically coupled to the semiconductor layers. In more detail, the semiconductor layers may include gate electrodes, source electrodes, and drain electrodes, and the first electrodes may be connected to the drain electrodes of the semiconductor layers.

According to an exemplary embodiment of the present invention, the power supply lines supply electric power to the cathode.

According to an exemplary embodiment of the present invention, an average diameter of the through-holes is 0.5 to 500 μm.

According to an exemplary embodiment of the present invention, a conductive material is filled in the through-holes, and the second electrode is connected to the conductive material.

Here, the conductive material may be a metal paste. The metal paste may include silver (Ag) paste, copper (Cu) paste, and/or aluminum (Al) paste. They may be used alone, or two or more of them may be mixed to be used.

According to an exemplary embodiment of the present invention, the second electrode is a light-transmitting electrode.

That is, the light emitting surfaces may be the second electrode, and the organic light emitting display device may be of top-emission type.

According to another embodiment of the present invention, there is provided a method of manufacturing an organic light emitting display device including the steps of: forming semiconductor layers on a substrate; forming power supply lines on the substrate such that the power supply lines are spaced apart from the semiconductor layers; forming insulation layers on the semiconductor layers and the power supply lines; forming first electrodes on the insulation layers; forming pixel defining layers such that the first electrodes are defined in units of pixels; forming light emitting layers on the first electrodes defined in units of pixels by the pixel defining layers; forming through-holes passing through the insulation layers and the pixel defining layers on the power supply lines such that at least some portions of the power supply lines are exposed; and forming a second electrode on the light emitting layers and the pixel defining layers such that the second electrode is electrically coupled to the power supply lines through the through-holes.

According to an exemplary embodiment of the present invention, the method further includes the step of forming hole injection layers and/or hole transport layers on the first electrodes, before the step of forming the light emitting layers.

According to an exemplary embodiment of the present invention, the method further includes the step of forming electron injection layers and/or electron transport layers on the light emitting layers, before the step of forming the second electrode.

According to an exemplary embodiment of the present invention, the first electrodes are anodes, and the second electrode is a cathode.

According to an exemplary embodiment of the present invention, in the step of forming the first electrodes, the first electrodes are electrically coupled to the semiconductor layers.

According to an exemplary embodiment of the present invention, the step of forming the semiconductor layers includes a step of forming gate electrodes, a step of forming source electrodes, and a step of forming drain electrodes; and the step of forming the first electrodes includes a step of connecting the first electrodes to the drain electrodes of the semiconductor layers.

According to an exemplary embodiment of the present invention, the power supply lines supply electric power to the cathode.

According to an exemplary embodiment of the present invention, the through-holes are formed by a laser.

According to an exemplary embodiment of the present invention, an average diameter of the through-holes is 0.5 to 500 μm.

According to an exemplary embodiment of the present invention, the method further includes the step of filling a conductive material in the through-holes before the step of forming the second electrode, and wherein in the step of forming the second electrode, the second electrode and the conductive material filled in the through-holes are connected to each other.

According to an exemplary embodiment of the present invention, the second electrode is formed of a light-transmitting material.

According to another embodiment of the present invention, there is provided an organic light emitting display device including: a substrate; semiconductor layers formed on the substrate; power supply lines formed on the substrate to be spaced apart from the semiconductor layers; insulation layers formed on the semiconductor layers and the power supply lines; first electrodes formed on the insulation layers and electrically coupled to the semiconductor layers; pixel defining layers defining the first electrodes in units of pixels; light emitting layers formed on the first electrodes defined by the pixel defining layers; through-holes formed on the power supply lines and passing through the insulation layers and the pixel defining layers; and a second electrode formed on the light emitting layers and the pixel defining layers and electrically coupled to the power supply lines through the through-holes.

According to another embodiment of the present invention, there is provided a method of manufacturing an organic light emitting display device including the steps of: forming semiconductor layers on a substrate; forming power supply lines on the substrate such that the power supply lines are spaced apart from the semiconductor layers; forming insulation layers on the semiconductor layers and the power supply lines; forming first electrodes on the insulation layers such that the first electrodes are electrically coupled to the semiconductor layers; forming pixel defining layers on the insulation layers such that the first electrodes are defined in units of pixels; forming light emitting layers on the first electrodes defined in units of pixels; forming through-holes passing through the insulation layers and the pixel defining layers such that at least some portions of the power supply lines are exposed; and forming a second electrode on the light emitting layers and the pixel defining layers such that the second electrode is electrically coupled to the power supply lines through the through-holes.

According to one embodiment of the present invention, since an upper electrode (e.g., the second electrode) can be electrically coupled to (e.g., connected to) the power supply lines through the through-holes, charges can be smoothly supplied to the upper electrode of the organic light emitting display device. As a result, light emitting efficiency of the organic light emitting display device can be enhanced.

According to one embodiment of the present invention, in particular, in the top-emission type organic light emitting display device, since the cathode, i.e. the upper electrode (e.g., the second electrode) located on the light emitting surface can be connected to the power supply lines located on the substrate through the through-holes, charges can be smoothly supplied to the cathode, thereby making it possible to enhance light emitting efficiency.

### BRIEF DESCRIPTION OF THE DRAWINGS

The above and other objects, features and advantages of the present invention will be more apparent from the following detailed description taken in conjunction with the accompanying drawings, in which:

FIG. 1 schematically illustrates a structure of an organic light emitting display device;

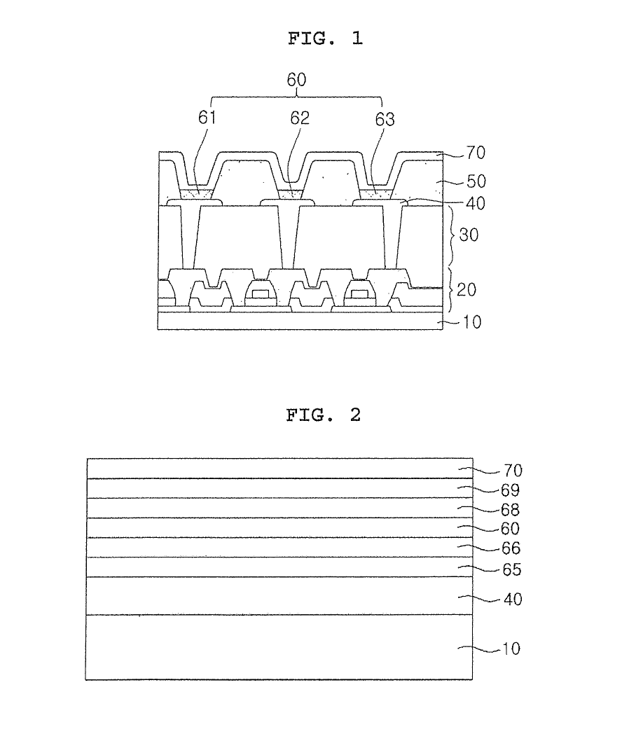

FIG. 2 illustrates a structure where multiple organic material layers are stacked on and under a light emitting layer of the organic light emitting display device;

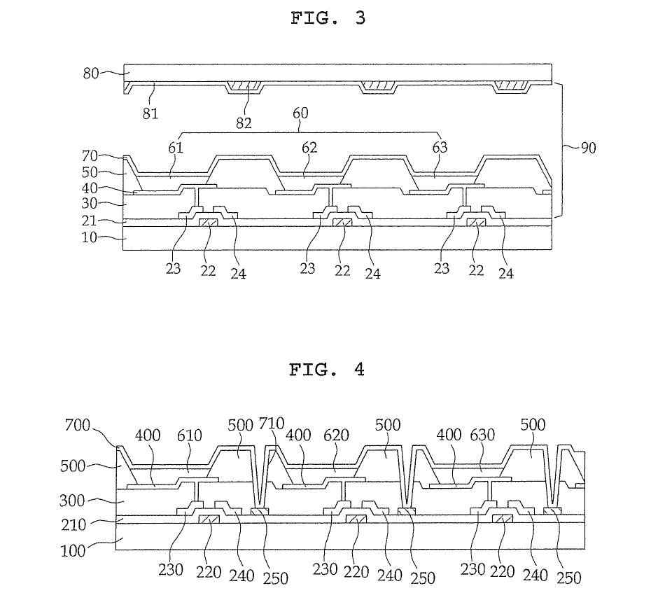

FIG. 3 illustrates a related organic light emitting display device more specifically;

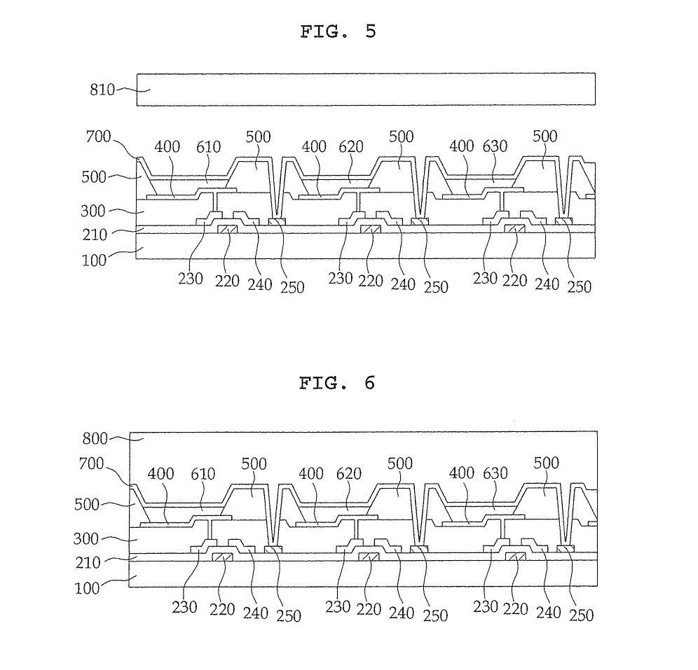

FIG. 4 illustrates an organic light emitting display device according to an embodiment of the present invention;

FIG. 5 illustrates an organic light emitting display device according to another embodiment of the present invention;

FIG. 6 illustrates an organic light emitting display device according to yet another embodiment of the present invention;

FIGS. 7A to 7G are views illustrating a method of manufacturing an organic light emitting display device according to an embodiment of the present invention; and

FIGS. 8A to 8D are views illustrating a method of manufacturing an organic light emitting display device according to another embodiment of the present invention.

FIG. 9 illustrates an organic light emitting display device according to another embodiment of the present invention.

### DETAILED DESCRIPTION

Hereinafter, exemplary embodiments of the present invention will be described in more detail with reference to the accompanying drawings. However, the scope of the present invention is not limited to the below-described embodiments and the accompanying drawings.

For reference, the elements and their shapes are schematically drawn or exaggerated in the drawings to help understanding of the present invention. In the drawings, the same/like reference numerals denote the same/like elements.

Further, when it is described that a layer or element is located on another layer or element, the layer or element may not only directly contact the other layer or element, but also one or more third layers or elements may be interposed therebetween.

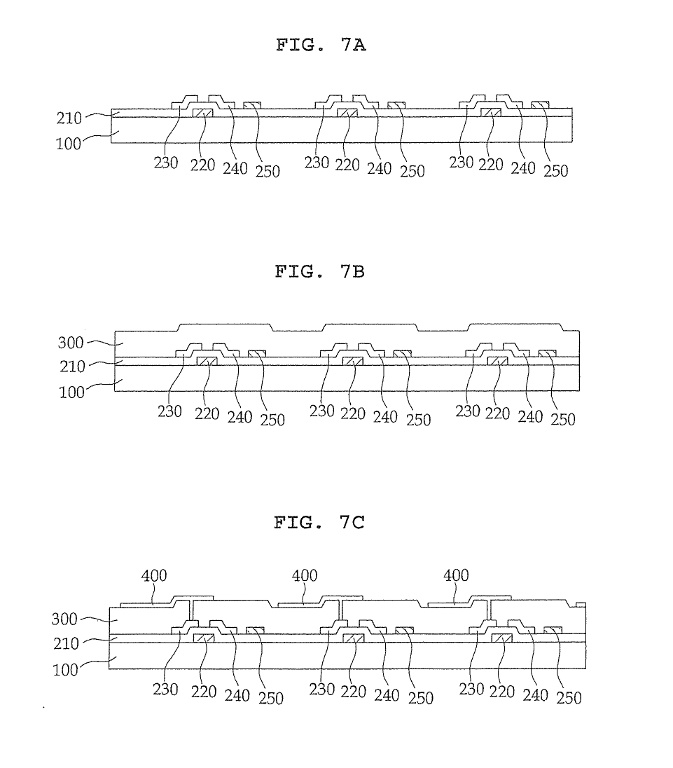

FIG. 4 schematically illustrates an organic light emitting display device according to an embodiment of the present invention.

The organic light emitting display device includes a substrate 100, semiconductor layers (including gate electrodes 220, source electrodes 230, and drain electrodes 240—the gate electrodes 220, the source electrodes 230, and the drain electrodes 240 being separated by an interlaying insulation (gate insulation) layer 210) formed on the substrate 100, power supply lines 250 formed on the substrate 100 to be spaced apart from the semiconductor layers 220, 230, and 240, insulation layers 300 formed on the semiconductor layers 220, 230, and 240 and the power supply lines 250, first electrodes 400 formed on the insulation layers 300, pixel defining layers 500 defining the first electrodes 400 in units of pixels, light emitting layers 610, 620, and 630 formed on the first electrodes 400 defined in units of pixels by the pixel defining layers 500, through-holes 710 formed on the power supply lines 250 and passing through the insulation layers 300 and the pixel defining layers 500, and a second electrode 700 formed on the light emitting layers 610, 620, and 630 and the pixel defining layers 500. Here, the second electrode 700 is electrically coupled to the power supply lines 250 through the through-holes 710.

According to an exemplary embodiment of the present invention, the first electrodes are anodes, and the second electrode is a cathode. Alternatively, the first electrodes may be cathodes and the second electrode may be an anode. Hereinafter, an embodiment where the first electrodes are anodes and the second electrode is a cathode will be described for consistency.

The organic light emitting display device according to the present invention may be of a bottom-emission type where the first electrodes act as light emitting surfaces or may be of a top-emission type where the second electrode acts as a light emitting surface. Hereinafter, a top-emission type organic light emitting display device where the second electrode acts as a light emitting surface will be described for consistency.

In the top-emission type, the second electrode 700 is a light-transmitting electrode. In addition, the first electrodes can be reflective electrodes.

In the following embodiments, the second electrode is a cathode, wherein the power supply lines are provided to supply electric power to the cathode.

In more detail, a substrate generally used for an organic light emitting display device may be arbitrarily selected and used for the substrate 100. As an example of the substrate, a glass substrate or a transparent plastic substrate having a suitable mechanical strength, a suitable thermal stability, a suitable transparency, and/or a suitable flat surface (which can be easily treated and has excellently water resistant (water-proofed) characteristics) may be used.

Also, a buffer layer may be disposed on the substrate 100 with a silicon oxide film, a silicon nitride film, an organic film, or a multilayered insulation layer by using chemical vapor deposition or physical vapor deposition. The buffer layer acts as a barrier which blocks or prevents moisture or gas generated in the lower substrate from influencing the upper device.

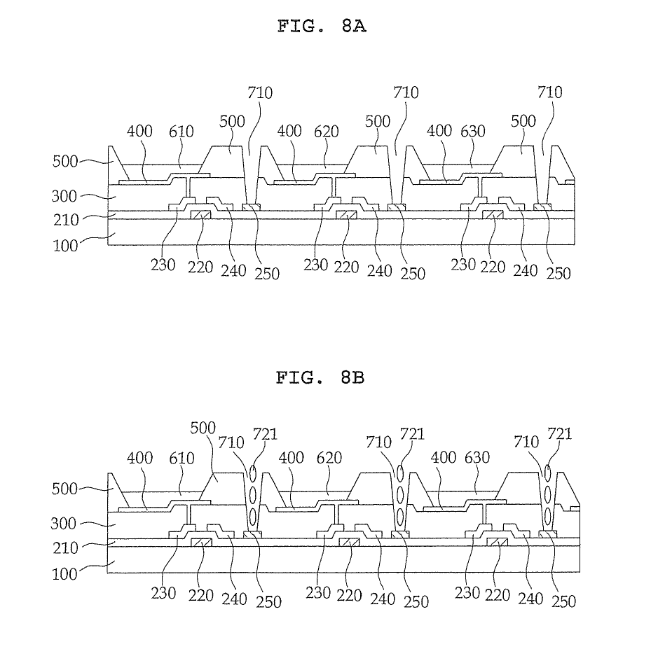

As can be seen in FIG. 7A, the semiconductor layers 220, 230, and 240 are disposed on the top surface of the substrate 100. As an example of the semiconductor layers 220, 230, and 240, a TFT is formed in the embodiment, and the semiconductor layers 220, 230, and 240 include the gate electrodes 220, the source electrodes 240, and the drain electrodes 230.

In order to form the TFT, i.e. the semiconductor layers 220, 230, and 240, a gate electrode material is deposited on the substrate 100 and then patterned to form the gate electrodes 220. Thereafter, an interlaying insulation layer, i.e. a gate insulation layer 210, is formed on the gate electrodes 220 and on the entire surface of the substrate 100. The interlaying insulation layer (gate insulation layer) 210 may be a silicon oxide film, a silicon nitride film, an organic film, or a multilayer thereof. Next, the drain electrodes 230 and the source electrodes 240 are formed on the interlaying insulation layer 210 at upper portions of the gate electrodes 220.

Also, as can be seen in FIG. 7A, power supply lines 250 are disposed to be spaced apart from the semiconductor layers 220, 230, and 240. The power supply lines 250 may be formed of a conductive material. For example, they may be formed of a metallic material such as gold (Au), silver (Ag), copper (Cu), and aluminum (Al), or may be formed of a transparent conductive oxide (TCO) such as ITO, IZO, and AZO. However, the material of the power supply lines 250 is not limited to the above-mentioned ones.

The width and thickness of the power supply lines may be arbitrarily determined as occasion demands. The width and thickness of the power supply lines may be varied according to the size of the display device, and may be varied according to an interval of the pixels of the light emitting layers. The power supply lines may be formed through deposition and sputtering.

After the semiconductor layers 220, 230, and 240 and the power supply lines 250 are formed as mentioned above, an insulation layer 300 is formed on the semiconductor layers and the power supply lines of the substrate (see FIG. 7B).

The insulation layer 300 may be formed of a silicon oxide film, a silicon nitride film, or an organic layer through chemical vapor deposition or physical vapor deposition, or may be formed of multiple layers that are stacked.

The insulation layer 300 is also referred to as a planarization layer.

First electrodes 400 are formed on the insulation layer 300 (see FIG. 7C). The first electrodes may be patterned and defined for red, green, and blue sub-pixels. In the embodiment, the first electrodes are anodes.

The first electrodes 400 may be transparent electrodes, semi-transparent electrodes or reflective electrodes, and may be formed of a transparent conductive oxide (TCO) such as, for example, indium tin oxide (ITO), indium zinc oxide (IZO), tin dioxide (SnO2), and zinc oxide (ZnO). The first electrodes 400 may be suitably modified, for example, may be modified to have a structure where the transparent conductive oxide (TCO) and a metal layer are stacked. The material and structure of the first electrodes 400 are not limited to the above-mentioned ones.

The first electrodes 400 are electrically coupled to the semiconductor layers 220, 230, and 240. In the embodiment, as illustrated in FIG. 7C, the drain electrodes 230 of the semiconductor layers 220, 230, and 240 are connected to the first electrodes 400.

Next, as can be seen in FIG. 7D, the first electrodes 400 are defined in units of pixels by forming pixel defining layers 500. The pixel defining layers 500 may be formed of an insulating material. The pixel defining layers 500 are also referred to as partition barriers or pixel separating walls. The pixel defining layers 500 may be formed by a method generally applied in the art to which the present invention pertains.

The first electrodes 400 may be patterned and defined in units of pixels into red pixels, green pixels, and blue pixels by the pixel defining layers 500.

Light emitting layers are formed on the first electrodes 400 defined in units of pixels by the pixel defining layers (see FIG. 7E). The light emitting layers include red light emitting layers 610, green light emitting layers 620, and blue light emitting layers 630.

The light emitting layers may be formed of an organic light emitting material. The organic light emitting material may be selected from those commercially available.

The light emitting layer forming method includes vacuum deposition, spin coating, casting, Langmuir-Blodgett (LB), and a method generally used in the art to which the present invention pertains may be employed.

Also, although not illustrated, at least one of hole injection layers and hole transport layers may be further disposed between the first electrodes 400 and the light emitting layers.

The hole injection layers are organic layers, and may be selectively formed through vacuum heat deposition or spin coating, etc. The material for forming the hole injection layer may be selected from those conventionally used in the art as the hole injecting materials.

The hole transport layers are also organic layers, and may be formed by various methods such as vacuum deposition, spin coating, casting, LB, etc.

Next, as can be seen in FIG. 7F, through-holes 710 passing through the pixel defining layers 500 and the insulation layer 300 are formed. The power supply lines 250 are exposed through the through-holes 710.

Although it is possible that the through-holes 710 pass through the light emitting layers 610, 620, and 630, they are designed to pass through the pixel defining layers 500 and the insulation layer 300 in the present embodiment, in consideration of the light emitting quality.

The average diameter of the through-holes 710 may range from 0.5 to 500 μm. Of course, the diameter range of the through-holes 710 may deviate from the above-mentioned range. Also, considering the power supply characteristics to the second electrode 700 via the through-holes 710 and the light emitting characteristics, the average diameter of the through-holes 710 is limited in range. If the diameter of the through-holes 710 is less than 0.5 μm, electric power may not be smoothly supplied to the second electrode, and if the diameter of the through-holes 710 exceeds 500 μm, the pixel defining layers 500 may be damaged. If an area occupied by the pixel defining layers 500 is sufficiently large, the diameter of the through-holes 710 may become larger.

The through-holes 710 may be formed by a laser. Such laser as being used for forming through-holes 710 in an organic material may be used without restriction.

The depth and diameter of the through-holes 710 may be adjusted by adjusting the number of laser irradiations. In the embodiment, a laser having a strength of 5 to 10 mJ/cm² may be used.

Next, as can be seen in FIG. 7G, the second electrode 700 is formed on the light emitting layers and the pixel defining layers 500 as a cathode. The second electrode 700 may be formed of a metal having a low work function, an alloy, an electrically conductive compound, and a mixture thereof. A detailed example includes lithium (Li), magnesium (Mg), aluminum (Al), aluminum-lithium (Al—Li), calcium (Ca), magnesium-indium (Mg—In), and magnesium-silver (Mg—Ag). A transmitting material such as ITO and IZO may be used to obtain a top-emission type light emitting device.

When the second electrode 700 is formed, the second electrode 700 extends into the through-holes 710. As the second electrode 700 extends into and/or through the through-holes 710, the second electrode 700 may be connected to the power supply lines 250.

The second electrode 700 may be formed through vacuum deposition or sputtering.

Although not illustrated in the drawings, at least one of electron transport layers and electron injection layers may be further disposed between the light emitting layers and the second electrode 700.

In one embodiment, the electron transport layers are formed of a material whose transport performance of the injected electrons is large. Also, the electron injection layers help inject electrons from the second electrode 700.

The electron transport layers and the electron injection layers may be formed and stacked through vacuum deposition, spin coating, or casting. Although the deposition condition depends on the used compound, it may be selected from a condition substantially the same as in the formation of the hole injection layers.

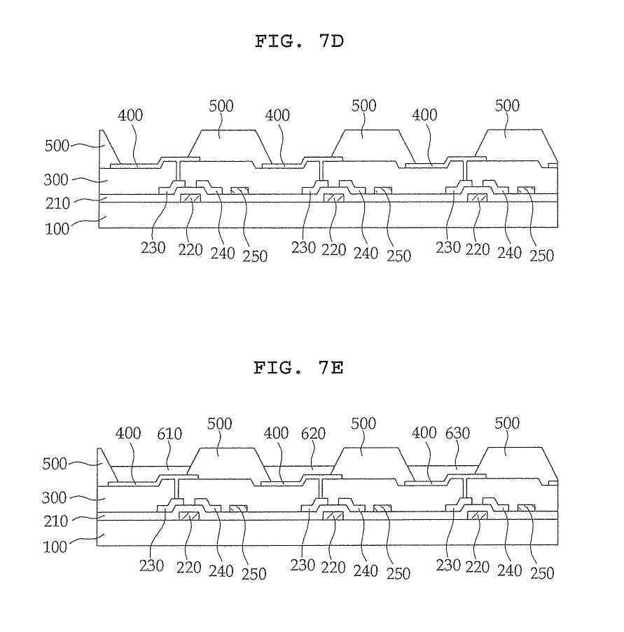

Referring to FIG. 5, a protective substrate 810 for protecting light emitting layers may be disposed in the organic light emitting display device.

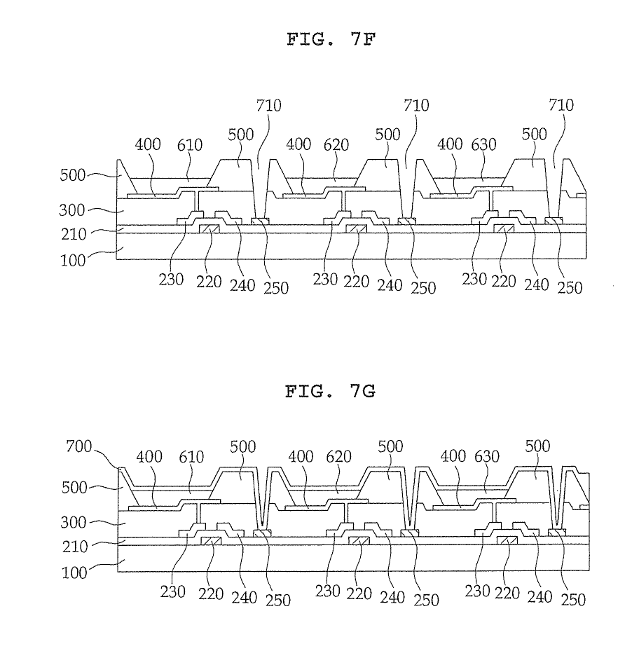

As illustrated in FIG. 6, a transparent capping layer 800 may be formed instead of the protective substrate.

According to another embodiment of the present invention, a conductive material may be filled in the through-holes, and the second electrode may be connected to the conductive material.

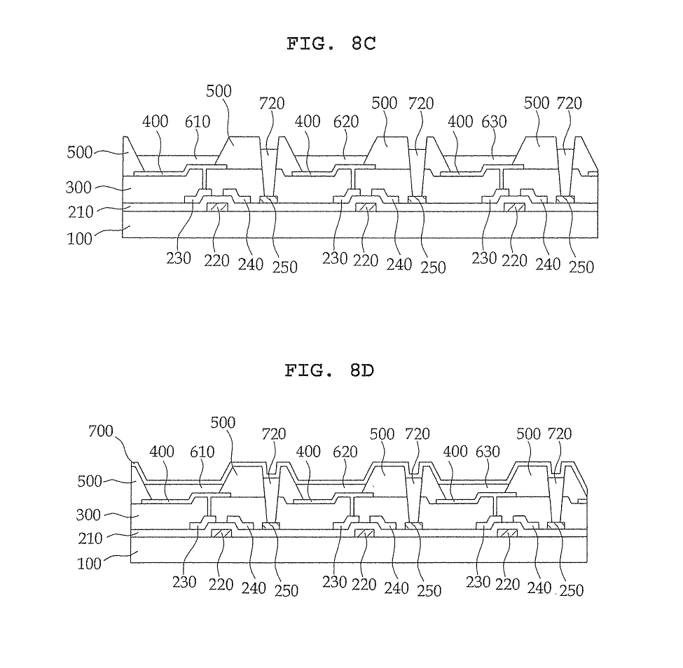

In more detail, through-holes 710 passing through the pixel defining layers 500 and the insulation layer 300 are formed as can be seen FIG. 8A.

Thereafter, as can be seen in FIG. 8B, as a conductive material (metal paste) 721 is injected into the through-holes 710, such that a conductive material 720 is filled as in FIG. 8C.

Here, the conductive material 721 may be formed of a metal paste. The metal paste includes silver (Ag) paste, copper (Cu) paste, and/or aluminum (Al) paste. They may be used alone, or two or more of them may be mixed to be used. The metal paste which can be used for the conductive material 720 shown in FIG. 8C is not limited to the above materials.

Thereafter, in the step of forming the second electrode 700, the second electrode 700 is connected to the conductive material filled in the through-holes 710 (FIG. 8D).

According to another embodiment of the present invention, there is provided an organic light emitting display device including: a substrate; semiconductor layers formed on the substrate; power supply lines formed on the substrate to be spaced apart from the semiconductor layers; insulation layers formed on the semiconductor layers and the power supply lines; first electrodes formed on the insulation layers and connected to the semiconductor layers; pixel defining layers defining the first electrodes in units of pixels; light emitting layers formed on the first electrodes defined by the pixel defining layers; through-holes formed on the power supply lines and passing through the insulation layers and the pixel defining layers; and a second electrode formed on the light emitting layers and the pixel defining layers and electrically coupled to the power supply lines through the through-holes.

According to another embodiment of the present invention, there is provided a method of manufacturing an organic light emitting display device including the steps of: forming semiconductor layers on a substrate; forming power supply lines on the substrate such that the power supply lines are spaced apart from the semiconductor layers; forming insulation layers on the semiconductor layers and the power supply lines; forming first electrodes on the insulation layers such that the first electrodes are connected to the semiconductor layers; forming pixel defining layers on the insulation layers such that the first electrodes are defined in units of pixels; forming light emitting layers on the first electrodes defined in units of pixels; forming through-holes passing through the insulation layers and the pixel defining layers such that some of the power supply lines are opened; and forming a second electrode on the light emitting layers and the pixel defining layers such that the second electrode is connected to the power supply lines through the through-holes.

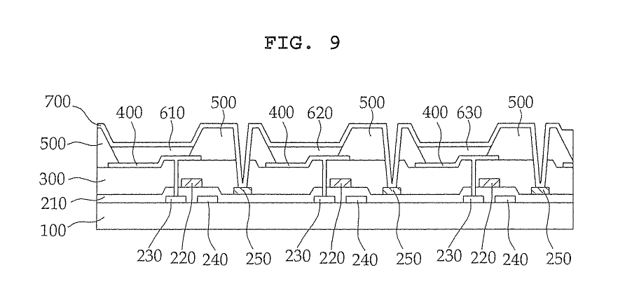

FIG. 9 illustrates another example of an organic light emitting display device according to another embodiment of the present invention.

In FIG. 9, as the examples of the semiconductor layers, thin film transistors are formed on the top surface of the substrate, and the semiconductor layers include gate electrodes 220, drain electrodes 230 and source electrodes 240. The thin film transistor (TFT) shown in FIG. 9 has a top gate structure.

In order to form the TFT, i.e. the semiconductor layers, a drain electrode material and a source electrode material are deposited on the substrate and patterned to form drain electrodes 230 and source electrodes 240. Then, an interlaying insulation layer 210 is formed on the drain electrodes 230, on the source electrodes 240 and on the entire surface of the substrate. Next, gate electrodes 220 are formed on the interlaying insulation layer 210. The other steps are the same with those described above explaining the steps of FIG. 7A to FIG. 7G.

The organic light emitting display device according to FIG. 9 may be of a bottom-emission type where the surface directed to the first electrodes 400 act as light emitting surfaces or may be of a top-emission type where the surface directed to the second electrode acts as a light emitting surface 700.

The above description discusses organic light emitting display devices and methods of manufacturing the same according to the present invention. In the above description of the present invention, the embodiments and drawings have been described in detail and restrictively, but the embodiments and the drawings may be suitably modified and the modifications also fall under the scope of the present invention, and equivalents thereof.

What is claimed is:

1. An organic light emitting display device comprising:
a substrate;
semiconductor layers on the substrate;
power supply lines on the substrate and spaced apart from the semiconductor layers;
insulation layers on the semiconductor layers and the power supply lines;
first electrodes on the insulation layers;
pixel defining layers defining the first electrodes in units of pixels;
light emitting layers on the first electrodes defined in units of pixels by the pixel defining layers;
through-holes on the power supply lines and passing through the insulation layers and the pixel defining layers; and
a second electrode on the light emitting layers and the pixel defining layers and electrically coupled to the power supply lines through the through-holes.

2. The organic light emitting display device as claimed in claim 1, wherein hole injection layers and/or hole transport layers are disposed between the first electrodes and the light emitting layers.

3. The organic light emitting display device as claimed in claim 1, wherein electron transport layers and/or electron injection layers are disposed between the light emitting layers and the second electrode.

4. The organic light emitting display device as claimed in claim 1, wherein the first electrodes are anodes, and wherein the second electrode is a cathode.

5. The organic light emitting display device as claimed in claim 1, wherein the first electrodes are electrically coupled to the semiconductor layers.

6. The organic light emitting display device as claimed in claim 1, wherein the semiconductor layers comprise gate electrodes, source electrodes, and drain electrodes, and wherein the first electrodes are connected to the drain electrodes of the semiconductor layers.

7. The organic light emitting display device as claimed in claim 1, wherein the power supply lines are configured to supply electric power to a cathode.

8. The organic light emitting display device as claimed in claim 1, wherein an average diameter of the through-holes is 0.5 to 500 μm.

9. The organic light emitting display device as claimed in claim 1, wherein a conductive material is filled in the through-holes, and wherein the second electrode is connected to the conductive material.

10. The organic light emitting display device as claimed in claim 1, wherein the second electrode is a light-transmitting electrode.

11. A method of manufacturing an organic light emitting display device, the method comprising:
forming semiconductor layers on a substrate;
forming power supply lines on the substrate to be spaced apart from the semiconductor layers;
forming insulation layers on the semiconductor layers and the power supply lines;
forming first electrodes on the insulation layers;
forming pixel defining layers to define the first electrodes in units of pixels;
forming light emitting layers on the first electrodes defined in units of pixels by the pixel defining layers;
forming through-holes to pass through the insulation layers and the pixel defining layers on the power supply lines to expose some portions of the power supply lines; and
forming a second electrode on the light emitting layers and the pixel defining layers to electrically couple the second electrode to the power supply lines through the through-holes.

12. The method as claimed in claim 11, further comprising:
forming hole injection layers and/or hole transport layers on the first electrodes, before the forming of the light emitting layers.

13. The method as claimed in claim 11, further comprising:
forming electron injection layers and/or electron transport layers on the light emitting layers, before the forming of the second electrode.

14. The method as claimed in claim 11, wherein in the forming of the first electrodes, the first electrodes are electrically coupled to the semiconductor layers.

15. The method as claimed in claim 11, wherein the forming of the semiconductor layers comprises: forming gate electrodes, forming source electrodes, and forming drain electrodes; and wherein the forming of the first electrodes comprises connecting the drain electrodes of the semiconductor layers to the first electrodes.

16. The method as claimed in claim 11, wherein the power supply lines are for supplying electric power to a cathode.

17. The method as claimed in claim 11, wherein the through-holes are formed by a laser.

18. The method as claimed in claim 11, wherein an average diameter of the through-holes is 0.5 to 500 μm.

19. The method as claimed in claim 11, further comprising filling a conductive material in the through-holes before the forming of the second electrode, and wherein in the forming of the second electrode, the second electrode and the conductive material filled in the through-holes are connected to each other.

20. The method as claimed in claim 11, wherein the second electrode is formed of a light-transmitting material.

21. An organic light emitting display device comprising:
a substrate;
semiconductor layers on the substrate;
power supply lines on the substrate to be spaced apart from the semiconductor layers;
insulation layers on the semiconductor layers and the power supply lines;
first electrodes on the insulation layers and electrically coupled to the semiconductor layers;
pixel defining layers defining the first electrodes in units of pixels;
light emitting layers on the first electrodes defined by the pixel defining layers;
through-holes on the power supply lines and passing through the insulation layers and the pixel defining layers; and
a second electrode on the light emitting layers and the pixel defining layers and electrically coupled to the power supply lines through the through-holes.

22. A method of manufacturing an organic light emitting display device, the method comprising:
forming semiconductor layers on a substrate;
forming power supply lines on the substrate to be spaced apart from the semiconductor layers;
forming insulation layers on the semiconductor layers and the power supply lines;
forming first electrodes on the insulation layers to be electrically coupled to the semiconductor layers;
forming pixel defining layers on the insulation layers to define the first electrodes in units of pixels;
forming light emitting layers on the first electrodes defined in units of pixels;
forming through-holes to pass through the insulation layers and the pixel defining layers to expose at least some portions of the power supply lines; and
forming a second electrode on the light emitting layers and the pixel defining layers to electrically couple the second electrode to the power supply lines through the through-holes.
